(19) United States
(12) Patent Application Publication
(10) Pub. No.: US 2014/0177364 A1
(43) Pub. Date: Jun. 26, 2014

(54) ONE-TIME PROGRAMMABLE MEMORY AND TEST METHOD THEREOF

(71) Applicant: SK HYNIX INC., Gyeonggi-do (KR)

(72) Inventor: Hyun-Su YOON, Gyeonggi-do (KR)

(73) Assignee: SK HYNIX INC., Gyeonggi-do (KR)

(21) Appl. No.: 13/844,937

(22) Filed: Mar. 16, 2013

(30) Foreign Application Priority Data
Dec. 20, 2012 (KR) 10-2012-0149975

(51) Int. Cl. G11C 29/00

(52) U.S. Cl. CPC G11C 29/00
USPC 365/201

(57) ABSTRACT

A one-time programmable memory device may include a normal cell array including a plurality of one-time programmable memory cells, which are programmable and accessible in the normal operation, a test cell array including one-time programmable memory cells, which are programmed at a given pattern in a test operation for determining a failed row and/or a failed column and are not accessible in the normal operation, a row circuit configured to control an operation of a row that is selected by a row address in the normal cell array, and a column circuit configured to access a column that is selected by a column address in the normal cell array.

### CROSS-REFERENCE TO RELATED APPLICATIONS

The present application claims priority of Korean Patent Application No. 10-2012-0149975, filed on Dec. 20, 2012, which is incorporated herein by reference in its entirety.

### BACKGROUND

1. Field

Exemplary embodiments of the present invention relate to a one-time programmable memory in which data is written only one time, and more particularly, to a technology of testing a one-time programmable memory.

2. Description of the Related Art

In general, data of a laser fuse is classified by whether the fuse has been cut by a laser or not. A laser fuse is programmable in a wafer state before the wafer is mounted in a package.

An electrical fuse (hereinafter, referred to as an e-fuse) is used to overcome such a limitation. The e-fuse uses a transistor that stores data by changing resistance between a gate and a drain/a source thereof.

FIG. 1 is a diagram illustrating an e-fuse formed of a transistor operating as a resistor or a capacitor.

Referring to FIG. 1, the e-fuse includes a transistor T having a gate G to which a power supply voltage is supplied and a drain/a source D/S to which a ground voltage is supplied.

When a normal power supply voltage, which is tolerable to the transistor T, is supplied to the gate G, the e-fuse operates as a capacitor C. Thus, there is no current flow between the gate G and the drain/the source D/S. However, when a high voltage, which is intolerable to the transistor T, is supplied to the gate G, gate oxide of the transistor T is broken to short the gate G and the drain/the source D/S, and thus the e-fuse operates as a resistor R. Accordingly, a current flows between the gate G and the drain/the source D/S of the e-fuse. The data of the e-fuse is recognized based on the resistance value between the gate G and the drain/the source D/S. To recognize the data of the e-fuse, two methods are used. First, the data of the e-fuse may be recognized directly without a separate sensing operation by increasing the size of the transistor T. Second, the data of the e-fuse may be recognized by sensing a current flowing through the transistor T using an amplifier. However, these two methods are disadvantageous in terms of a circuit size because the transistor T of the e-fuse is designed to have a large transistor size or an amplifier for amplifying data should be provided in each e-fuse.

As disclosed in U.S. Pat. No. 7,269,047, researches are being carried out on schemes for reducing a circuit area occupied by e-fuses in such a way as to configure the e-fuses in an array form.

FIG. 2 is a configuration diagram illustrating a conventional cell array including c-fuses.

Referring to FIG. 2, the cell array 200 includes memory cells 201 to 216 arranged in N rows and M columns. The memory 201 includes a program element M1 and a switching element S1, the memory 202 includes a program element M2 and a switching element S2 the memory 203 includes a program element M3 and a switching element S3, the memory 204 includes a program element M4 and a switching element S4, the memory 205 includes a program element M5 and a switching element S5, the memory 206 includes a program element M6 and a switching element S6, the memory 207 includes a program element M7 and a switching element S7, the memory 208 includes a program element M8 and a switching element S8, the memory 209 includes a program element M9 and a switching element S9, the memory 210 includes a program element M10 and a switching element 510, the memory 211 includes a program element M11 and a switching element 511, the memory 212 includes a program element M12 and a switching element 512, the memory 213 includes a program element M13 and a switching element 513 the memory 214 includes a program element M14 and a switching element 514, the memory 215 includes a program element M15 and a switching element 515, and the memory 216 includes a program element M16 and a switching element 516. The program elements M1 to M16 are e-fuses having characteristics of a resistor or a capacitor based on whether they are ruptured or not. That is, the e-fuses M1 to M16 may be regarded as resistive program elements that store data according to the size of resistance thereof. The switching elements S1 to S16 connect the program elements M1 to M16 to column lines BL1 to BLM, respectively, based on the control of row lines WLR1 to WLRN.

Hereinafter, based on the assumption that a second row is selected, and an M^{th} column is selected. That is, the memory cell 208 is selected. A description will be provided for a voltage that is supplied to the selected memory cell 208 and unselected memory cells 201 to 207 and 209 to 219 in program and read operations.

Program Operation

The row line WLR2 of the selected row is activated and the other row lines WLR1 and WLR3 to WLRN are deactivated. Thus, the witching elements S5 to S8 are turned on and the switching elements S1 to S4 and S9 to S16 are turned off. A high voltage (in general, a high voltage obtained by pumping a power supply voltage), which may break gate oxide of the e-fuse, is supplied to a program/read line WLP2 of the selected row, and a low level voltage (for example, a ground voltage) is supplied to the other program/read lines WLP1 and WLP3 to WLPN. The selected column line BLM is connected to a data access circuit, and the unselected column lines BLM1 to BLM-1 are floated. When inputted data is program data (for example, “1”), the data access circuit drives the selected column line BLM to a ‘low’ level and allows the program element M8 of the selected memory cell 208 to be programmed (ruptured). When the inputted data is not the program data (for example, “0”), the data access circuit drives the selected column line BLM to a ‘high’ level and substantially prevents the program element M8 of the selected memory cell 208 from being programmed. Since the unselected column lines BLM1 to BLM-1 are floated, the program elements M5 to M7 are not programmed even though a high voltage is supplied to gates thereof.

Read Operation

The row line WLR2 of the selected row is activated and the other row lines WLR1 and WLR3 to WLRN are deactivated. Thus, the switching elements S5 to S8 are turned on, and the switching elements S1 to S4 and S9 to S16 are turned off. A voltage (in general, a power supply voltage), which is appropriate for the read operation, is supplied to the program/read line WLP2 of the selected row, and a low level voltage (for example, a ground voltage) is supplied to the other program/read lines WLP1 and WLP3 to WLPN. The selected column line BLM is connected to the data access circuit and the unselected column lines BLM1 to BLM-1 are floated. When a current flows through the selected column line BLM, the data access circuit recognizes that the program element M8 is programmed (recognizes data of the memory cell 208 as “1”). When no current flows through the selected column line BLM, the data access circuit recognizes that the program element M8 is not programmed (recognizes data of the memory cell 208 as “0”).

So far, one column line BLM of the column lines BL1 to BLM is selected as an example. However, several column lines may be selected at one time. That is, several memory cells belonging to one row may be simultaneously programmed/read.

FIG. 3 is a configuration diagram illustrating a conventional e-fuse array circuit including the cell array 200 shown in FIG. 2.

Referring to FIG. 3, the e-fuse array circuit includes the cell array (200 of FIG. 2), a row circuit 310, a column decoder 320, and a data access circuit 330.

The row circuit 310 controls the row lines WLR1 to WLRN and the program/read lines WLP1 to WLPN and allows the program and read operations to be performed as described above. An address ROW_ADD inputted to the row circuit 310 designates a row selected from a plurality of rows, and a program/read signal PG/RD inputted to the row circuit 310 instructs the program operation or the read operation.

The column decoder 320 connects a column line, which is selected from the column lines BL1 to BLM by an address COL_ADD, to the data access circuit 330.

The data access circuit 330 takes charge of data access of column lines selected by the column decoder 320. The data access circuit 330 controls the selected column line to be programmed/non-programmed based on input data DI in the program operation, and detects whether a current flows through the selected column lines and outputs a detect result as output data DO in the read operation.

In the case of a memory such as an e-fuse array circuit, when data is programmed once, the memory may not be returned to a state before the data is programmed or may not be programmed with data again. Thus, a memory such as an e-fuse array circuit, in which data is programmable only once, is called a one-time programmable memory. In the case of a general memory other than the one-time programmable memory, a test of the memory is performed by writing data in the memory and then confirming whether the data is normally written. However, in the case of the one-time programmable memory, after data is written, since additional use of the one-time programmable memory may be limited, a test for memory cells may not be possible. Particularly, whether a row circuit or a column circuit for controlling the memory cells normally operates may not be tested.

### SUMMARY

Exemplary embodiments of the present invention are directed to a technology that enables a test for circuits, such as a row circuit and a column circuit, for controlling a cell array in a one-time programmable memory.

In accordance with an embodiment of the present invention, a method for testing a one-time programmable memory with a test row and/or a test column includes programming one-time programmable memory cells corresponding to all columns of a test row and/or all rows of a test column, reading data programmed in the one-time programmable memory cells, and determining a failed row and/or a failed column using the read data. The method may further include storing the failed row and the failed column in a separate memory space.

In accordance with another embodiment of the present invention, a one-time programmable memory device includes a cell array including a plurality of one-time programmable memory cells arranged in a plurality of normal rows, one or more test rows, a plurality of normal columns, and one or more test columns, a row circuit configured to control an operation of a row that is selected by a row address in the cell array, and a column circuit configured to access a column that is selected by a column address in the cell array. To determine a failed row and a failed column in a test operation, one-time programmable memory cells corresponding to all columns of the test row and all rows of the test column are programmed, and data programmed in one-time programmable memory cells is read.

In accordance with another embodiment of the present invention, a one-time programmable memory device includes a normal cell array including a plurality of one-time programmable memory cells, which are programmable and accessible in the normal operation, a test cell array including one-time programmable memory cells, which are programmed at a given pattern in a test operation for determining a failed row and/or a failed column and are not accessible in the normal operation, a row circuit configured to control an operation of a row that is selected by a row address in the normal cell array, and a column circuit configured to access a column that is selected by a column address in the normal cell array.

In accordance with an embodiment of the present invention, a test of a row circuit and a column circuit for controlling a cell array in a one-time programmable memory may be performed.

### BRIEF DESCRIPTION OF THE DRAWINGS

FIG. 1 is a diagram illustrating an e-fuse including a transistor and an operation of the e-fuse as a resistor or a capacitor.

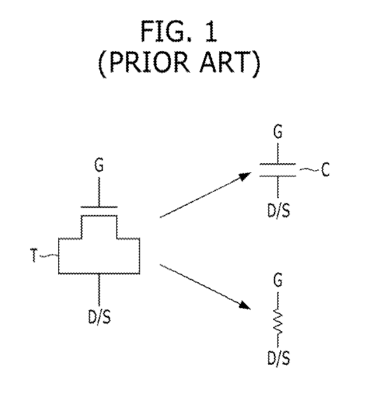

FIG. 2 is a configuration diagram illustrating a conventional cell array including e-fuses.

FIG. 3 is a configuration diagram illustrating a conventional e-fuse array circuit including a cell array shown in FIG. 2.

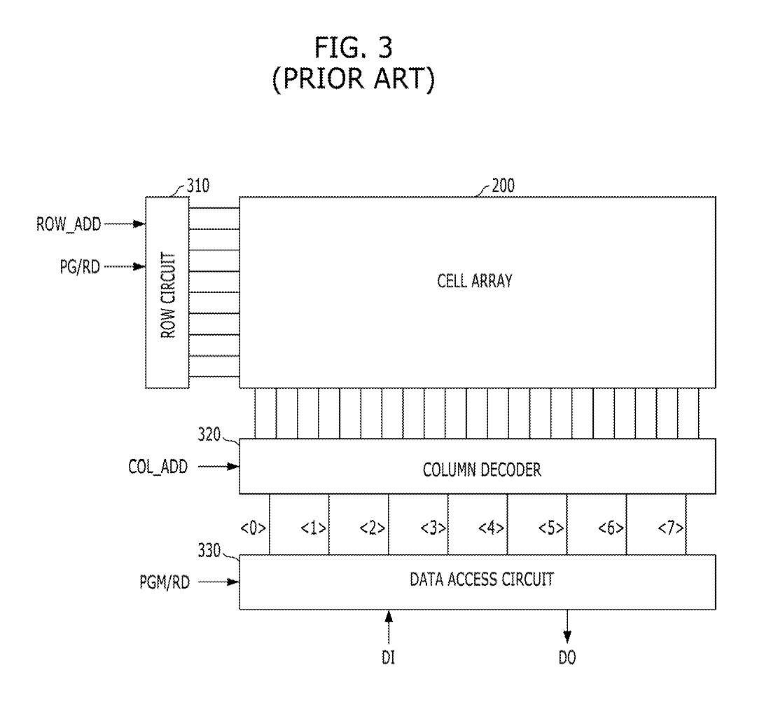

FIG. 4 is a configuration diagram illustrating a cell array of a one-time programmable memory in accordance with an embodiment of the present invention.

FIG. 5 is a configuration diagram illustrating a one-time programmable memory in accordance with the embodiment of the present invention.

FIG. 6 is a flowchart illustrating a test method of a one-time programmable memory in accordance with the embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, reference numerals correspond directly to the like parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

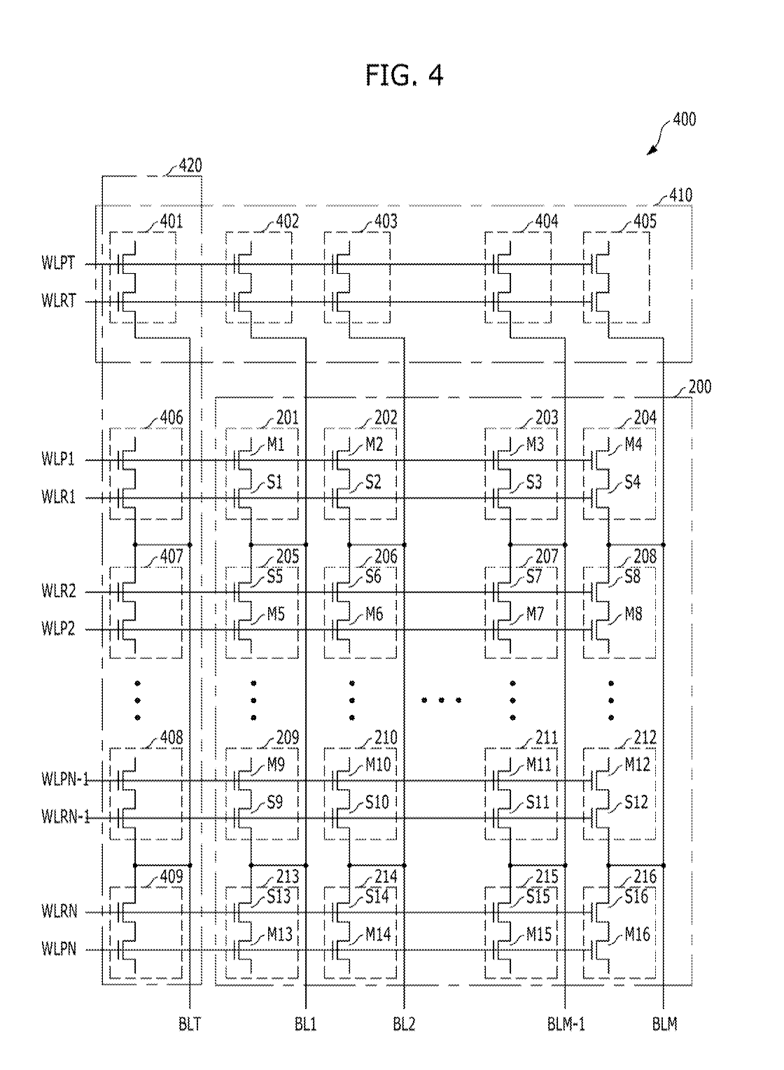

FIG. 4 is a configuration diagram illustrating a cell array of a one-time programmable memory in accordance with an embodiment of the present invention.

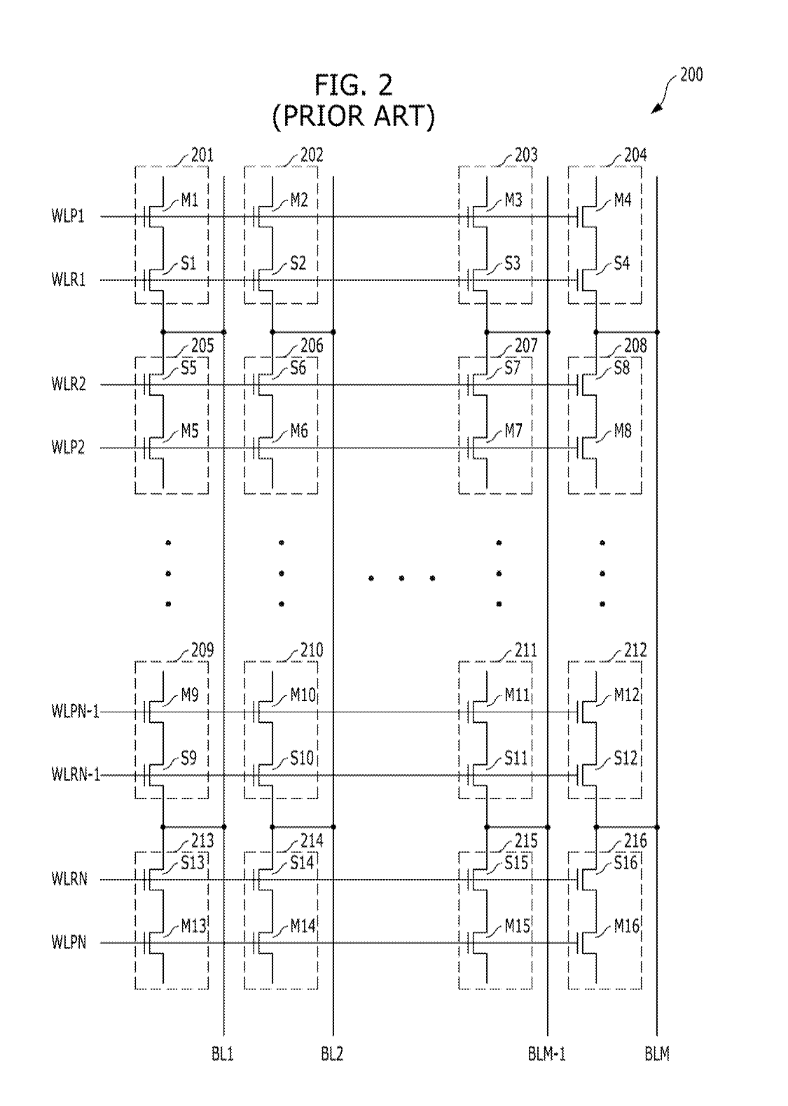

Referring to FIG. 4, a cell array 400 includes a conventional cell array (200, refer to FIG. 2), a test row 410, and a test column 420. Memory cells 401 to 405 of the test row 410 are not accessed in a normal operation and are accessed only in a test operation. Similarly, memory cells 401 and 406 to 409 of the test column 420 are not accessed in the normal operation and are accessed only in the test operation.

The memory cells 401 to 409 corresponding to the test row 410 and the test column 420 are substantially equal to the memory cells 201 to 216 in terms of a configuration and an operation, except that the memory cells 401 to 409 are programmed and read in the test operation. For reference, the test row 410 includes a test program/read line WLPT and a test row line WLP2, and the test column 420 includes a test column line BLT.

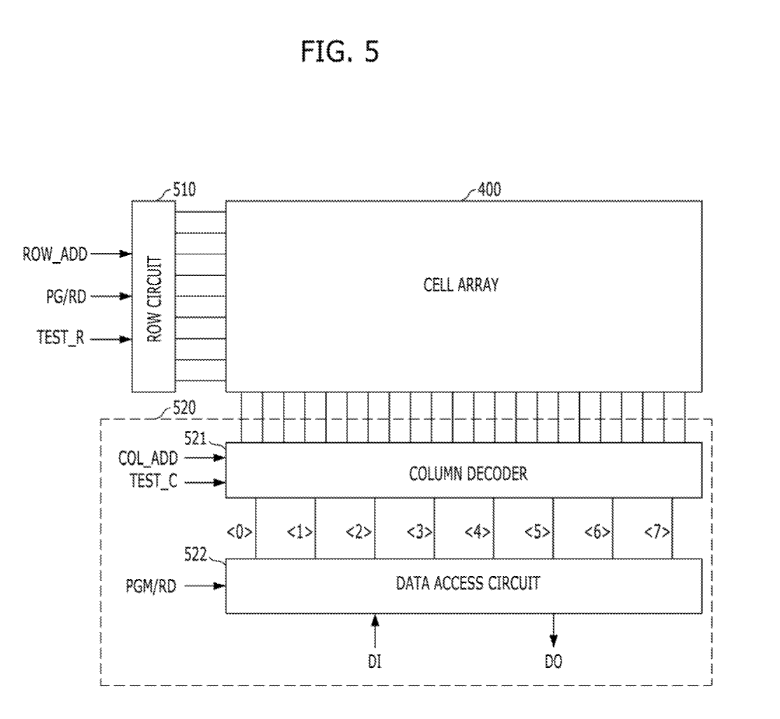

FIG. 5 is a configuration diagram illustrating the one-time programmable memory in accordance with the embodiment of the present invention.

Referring to FIG. 5, the one-time programmable memory includes the cell array 400, a row circuit 510, and a column circuit 520.

The cell array 400 includes memory cells arranged in a plurality of rows and a plurality of columns. The structure of the cell array 400 is illustrated in FIG. 4.

The row circuit 510 controls the normal row lines WLR1 to WLRN and the normal program/read lines WLP1 to WLPN and allows the program and read operations of the normal memory cells 201 to 216 to be performed. A row address ROW_ADD inputted to the row circuit 510 designates a row selected from a plurality of normal rows, and a program/read signal PG/RD inputted to the row circuit 510 instructs the program operation or the read operation. A test row signal TEST_R controls the row circuit 510 to select the test row 410. When the test row signal TEST_R is activated, the row circuit 510 does not select one of the normal rows and selects the test row 410 based on the row address ROW_ADD. In the embodiment, the test row signal TEST_R is used and the test row 410 is selected when the test row signal TEST_R is activated. However, the test row 410 may be selected based on a combination of the row addresses ROW_ADD without using the test row signal TEST_R.

The column circuit 520 programs program data DI in a selected column of the cell array 400 or reads read data DO from the selected column. Such a column circuit 520 may include a column decoder 521 and a data access circuit 522. The column decoder 521 connects a column line, which is selected from the column lines BL1 to BLM by a column address COL_ADD to the data access circuit 522. A test column signal TEST_C controls the column decoder 521 to select the test column 420. When the test column signal TEST_C is activated, the column decoder 521 does not select one of the normal columns and selects the test column 420. In the embodiment, the test column signal TEST_C is used and the test column 420 is selected when the test column signal TEST_C is activated. However, the test column 420 may be selected based on a combination of the column addresses COL_ADD without using the test column signal TEST_C. The data access circuit 522 takes charge of data access of column lines selected by the column decoder 521. The data access circuit 522 controls memory cells of the selected column line to be programmed/non-programmed based on program data DI inputted from an exterior in the program operation and detects whether a current flows through the selected column lines and outputs a detect result as read data DO in the read operation.

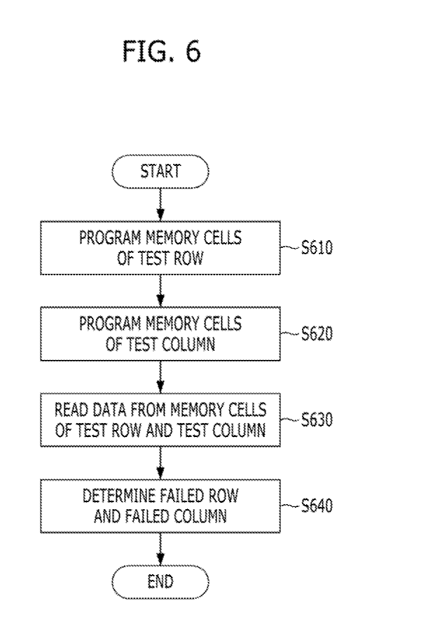

FIG. 6 is a flowchart illustrating a test method of the one-time programmable memory in accordance with the embodiment of the present invention.

Referring to FIGS. 4 to 6, all the memory cells 401 to 405 of the test row 410 are programmed at step S610. That is, data of “1” is written in the memory cells 401 to 405. Programming the memory cells 401 to 405 of the test row 410 may be performed by executing the program operation with the change of the column address COL_ADD in the state in which the test row signal TEST_R is activated, and by activating the test row signal TEST_R and the test column signal TEST_C and executing the program operation.

The memory cells 406 to 409 of the test column 420 are programmed at step S620. That is, data of “1” is written in the memory cells 406 to 409. Since the memory cell 401 belonging to the test column 420 has already been programmed in step S610 the memory cell 401 is not programmed again. Programming the memory cells 406 to 409 may be performed by executing the program operation with the change of the row address ROW_ADD in the state in which the test column signal TEST_C is activated.

Data is read from the memory cells 401 to 409 belonging to the test row 410 and the test column 420 at step S630. Reading the data from the memory cells 401 to 405 may be performed by executing the read operation with the change of the column address COL_ADD in the state in which the test row signal TEST_R is activated, and by activating the test row signal TEST_R and the test column signal TEST_C and executing the read operation. Furthermore, reading the data from the memory cells 406 to 409 may be performed by executing the read operation with the change of the row address ROW_ADD in the state in which the test column signal TEST_C is activated.

Based on the data read in step S630 a failed row and a failed column are determined at step S640. A row or a column corresponding to a memory cell, from which data of “0” is read, may be determined as a failed row or a failed column. For example, when “0” is read only from the memory cell 406 and 1″ is read from the other memory cells 401 to 405 and 407 to 409, a first row (a row corresponding to WLR1 and WLP1) may be determined to be failed. Furthermore, when “0” is read only from the memory cell 405 and “1” is read from the other memory cells 401 to 404 and 406 to 409, a last column (a column corresponding to BLM) may be determined to be failed. The failed row indicates that lines of a corresponding row are failed or the row circuit 510 does not correctly control a corresponding row. For example, when a third row is failed, it indicates that the row line WLR3 or the program/read line WLP3 is failed, or the row circuit 510 does not correctly control the row line WLR3 or the program/read line WLP3. The failed column indicates that lines of a corresponding column are failed or the column circuit 520 does not correctly control a corresponding column. For example, when a 30^{th} column is failed, it indicates that the column line is failed, or the column circuit 520 does not correctly control the column line.

In this way, the steps S610, S620, S630, and S640 are performed, so that it may be possible to confirm whether the row lines WLR1 to WLRN, the program/read lines WLP1 to WLPN, the column lines BL1 to BLM, the row circuit 510, and the column circuit 520 in the one-time programmable memory is failed.

Information of the failed row and the failed column, which are determined to be failed through the steps S610, S620, S630, and S640, may be stored in a separate memory space (for example, a laser fuse or another nonvolatile program element) in the one-time programmable memory, and the failed row and the failed column may be prevented from being accessed in the normal operation. Furthermore, the failed row and the failed column may be replaced (repaired) with a redundancy row and a redundancy column. In addition, the one-time programmable memory from which the failed row and the failed column have been found may be discarded. Since a technology of substantially preventing a row or a column determined to be failed from being accessed or of repairing the row or the column determined to be failed is well-known to those skilled in the art, a detailed description thereof will be omitted.

While the present invention has been described with respect to the specific embodiments, it should be noted that the embodiments are for describing, not limiting, the present invention. Further, it should be noted that the present invention may be achieved in various ways through substitution, change, and modification, by those skilled in the art without departing from the scope of the present invention.

Particularly, in the aforementioned embodiment, an e-fuse array circuit is used as a one-time programmable memory. However, the embodiments of the present invention that enable a test of lines and peripheral circuits by separately providing a test row and a test column and programming memory cells corresponding to the test row and the test column may be used to test all types of one-time programmable memories.

What is claimed is:

1. A method for testing a one-time programmable memory with a test row and/or a test column, the method comprising:
programming one-time programmable memory cells corresponding to all columns of a test row and/or all rows of a test column;
reading data programmed in the one-time programmable memory cells; and
determining a failed row and/or a failed column using the read data.

2. The method of claim 1, further comprising:
storing the failed row and the failed column in a separate memory space.

3. The method of claim 1, wherein the columns include the test column and normal columns, and the rows include the test row and normal rows.

4. The method of claim 1, wherein the test column and the test row are programmable and accessible in a test operation.

5. The method of claim 2, wherein, when the read data is not identical to the programmed data, a column or a row of a corresponding one-time programmable memory cell is determined as the failed column or the failed row.

6. A one-time programmable memory device comprising:
a cell array including a plurality of one-time programmable memory cells arranged in a plurality of normal rows, one or more test rows, a plurality of normal columns, and one or more test columns;
a row circuit configured to control an operation of a row that is selected by a row address in the cell array; and
a column circuit configured to access a column that is selected by a column address in the cell array,
wherein, to determine a failed row and a failed column in a test operation, one-time programmable memory cells corresponding to all columns of the test row and all rows of the test column are programmed, and data programmed in one-time programmable memory cells is read.

7. The one-time programmable memory device of claim 6, wherein the test row and the test column are positioned at a periphery of the cell array.

8. The one-time programmable memory device of claim 6, each of the one-time programmable memory cells comprises:
an e-fuse element configured to be controlled by program/read line of a corresponding row; and
a switching element configured to connect the e-fuse element to a column line of a corresponding column based on control of a row line of the corresponding row.

9. The one-time programmable memory device of claim 8, wherein the row circuit is configured to supply an activation voltage to a row line corresponding to a selected row and supply a program voltage to a program/read line corresponding to the selected row in a program operation, and to supply the activation voltage to the row line corresponding to the selected row and supply a read voltage to the program/read line corresponding to the selected row in a read operation.

10. The one-time programmable memory device of claim wherein the column circuit comprises:
a column decoder configured to select a column line from a plurality of column lines in response to a column address; and
a sense amplifier configured to supply a low voltage to a column line selected by the column decoder in the program and read operations, and to determine data by confirming that a current flows through the selected column line in the read operation.

11. The one-time programmable memory device of claim 6, wherein a row and a column determined as the failed row and the failed column in the test operation are prevented from being accessed in a normal operation.

12. A one-time programmable memory device comprising:
a normal cell array including a plurality of one-time programmable memory cells, which are programmable and accessible in the normal operation;
a test cell array including one-time programmable memory cells, which are programmed at a given pattern in a test operation for determining a failed row and/or a failed column and are not accessible in the normal operation;
a row circuit configured to control an operation of a row that is selected by a row address in the normal cell array; and
a column circuit configured to access a column that is selected by a column address in the normal cell array.

13. The one-time programmable memory device of claim 12, wherein the plurality of one-time programmable memory cells included in the normal cell array forms a plurality of normal rows and a plurality of normal columns.

14. The one-time programmable r memory device of claim 12, wherein the one-time programmable memory cells in the test cell array forms one or more test rows and/or one or more test columns.
